(19) United States
(12) Patent Application Publication
(10) Pub. No.: US 2024/0114697 A1
(43) Pub. Date: Apr. 4, 2024

(54) GAIN CELL USING PLANAR AND TRENCH FERROELECTRIC AND ANTI-FERROELECTRIC CAPACITORS FOR EDRAM

(71) Applicant: Intel Corporation, Santa Clara, CA (US)

(72) Inventors: Shriram SHIVARAMAN, Hillsboro, OR (US); Sou-Chi CHANG, Portland, OR (US); Sourav DUTTA, Hillsboro, OR (US); Uygar E. AVCI, Portland, OR (US)

(21) Appl. No.: 17/958,279

(22) Filed: Sep. 30, 2022

(51) Int. Cl. H01L 27/11507

(52) U.S. Cl. CPC H01L 27/11507

(57) ABSTRACT

Embodiments disclosed herein include a memory device. In an embodiment, the memory device comprises a first transistor, where the first transistor is an access transistor to write data. In an embodiment, the memory device further comprises a ferroelectric capacitor for storing data. In an embodiment, the memory device further comprises a second transistor, where the second transistor is a sense transistor to read the data stored on the ferroelectric capacitor.

### TECHNICAL FIELD

Embodiments of the disclosure are in the field of semiconductor structures and processing and, in particular, to embedded dynamic random-access memory (eDRAM) that includes trench and/or planar ferroelectric capacitors in a two transistor one capacitor (2T-1C) architecture.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1 is a circuit diagram of an embedded dynamic random-access memory (eDRAM) that includes a one transistor, one capacitor (1T-1C) architecture.

FIG. 2 is a circuit diagram of an eDRAM that includes a two transistor, one capacitor (2T-1C) architecture, in accordance with an embodiment.

FIG. 3A is a cross-sectional illustration of an eDRAM cell with a trench capacitor, in accordance with an embodiment.

FIG. 3B is a cross-sectional illustration of an eDRAM cell that includes a planar capacitor, in accordance with an embodiment.

FIG. 4 is a cross-sectional illustration of a nanowire-based transistor that can be used in an eDRAM cell, in accordance with an embodiment.

FIG. 5 is a cross-sectional illustration of a fin-based transistor that can be used in an eDRAM cell, in accordance with an embodiment.

FIG. 6 illustrates a computing device in accordance with one implementation of an embodiment of the disclosure.

FIG. 7 illustrates an interposer that includes one or more embodiments of the disclosure.

### DESCRIPTION OF THE EMBODIMENTS

Embodiments described herein comprise embedded dynamic random-access memory (eDRAM) that includes trench and/or planar ferroelectric capacitors in a two transistor one capacitor (2T-1C) architecture. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

In order to provide context, embedded dynamic random-access memory (eDRAM) architectures are beginning to use ferroelectric capacitors for the data storage unit in the memory cell. Single ferroelectric capacitors with a single access transistor will not have enough signal to reliably read the data as the capacitor size is scaled to smaller dimensions. Accordingly, current solutions use larger capacitors in order to provide the necessary signal level. This leads to larger memory cell size and, thus, lower density memory.

Accordingly, embodiments disclosed herein include the use of a second transistor as a read-out device. The charge of the capacitor is converted by the transconductance of the transistor into a readout current, and can enable the readout of a smaller capacitor charge. Such an architecture can accommodate smaller ferroelectric capacitors with smaller signals. Additionally, embodiments provide independent read and write paths that can be used for improving read/write margins independently. Embodiments may also provide a pathway for non-destructive read operations if there is a capacitance difference between the two polarization states.

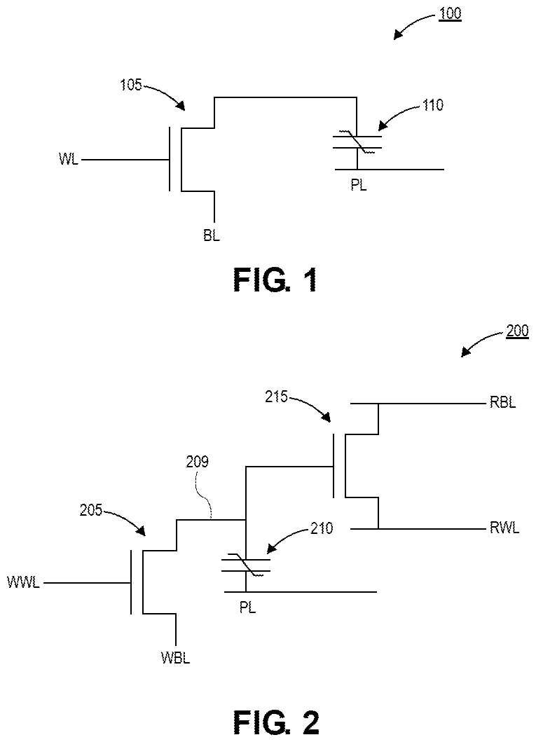

Referring now to FIG. 1, a circuit diagram of an existing eDRAM bit cell 100 is shown. The bit cell 100 may include a first transistor 105 and a ferroelectric capacitor 110. The gate of the first transistor 105 is coupled to a wordline (WL), and a source of the first transistor 105 is coupled to a bit line (BL). The drain of the first transistor 105 is coupled to a terminal of the ferroelectric capacitor 110. The other terminal of the ferroelectric capacitor 110 is coupled to a plate line (PL). As noted above, the bit cell 100 is limited because the ferroelectric capacitor 110 needs to be relatively large in order to provide the necessary signal to read the data from the bit cell 100.

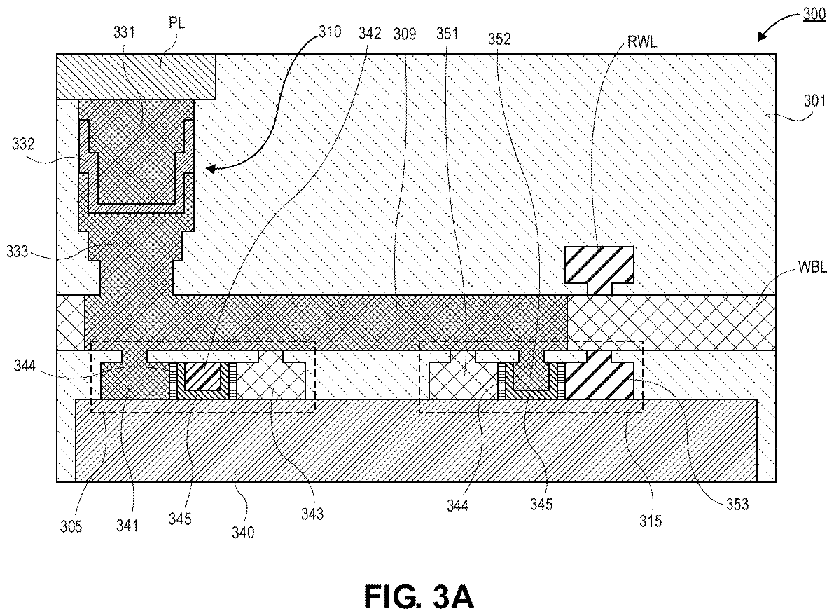

Accordingly, embodiments disclosed herein include an eDRAM bit cell 200 that includes a 2T-1C architecture. An example of such a bit cell 200 is provided in the circuit diagram shown in FIG. 2. As shown, a first transistor 205 is coupled to a node 209. One terminal of the ferroelectric capacitor 210 is also coupled to the node 209. Additionally, a gate of the second transistor 215 is coupled to the node 209. The first transistor 205 may be referred to as an access transistor 205 and is responsible for writing data to the bit cell 200. The second transistor 215 may be referred to as the sense transistor and is responsible for reading data from the bit cell 200.

In an embodiment, the first transistor 205 may have a gate that is coupled to the write word line (WWL), and a source that is coupled to a write bit line (WBL). The second transistor 215 may have a source that is coupled to a read word line (RWL), and a drain that is coupled to a read bit line (RBL). The terminal of the ferroelectric capacitor 210 opposite from the node 209 is coupled to the PL.

In an embodiment, the bit cell 200 is capable of either destructive readout or non-destructive readout. In the case of destructive readout, the second transistor 215 gate capacitance (C_{gate}) is larger than the ferroelectric capacitor capacitance (C_{FE}), so that more of the read voltage drops across C_{FE} and switches its polarization. In the case of a non-destructive readout, the ferroelectric capacitor has a different small signal capacitance between the two polarization states. In this case, C_{gate} can be comparable to (or smaller) than C_{FE}.

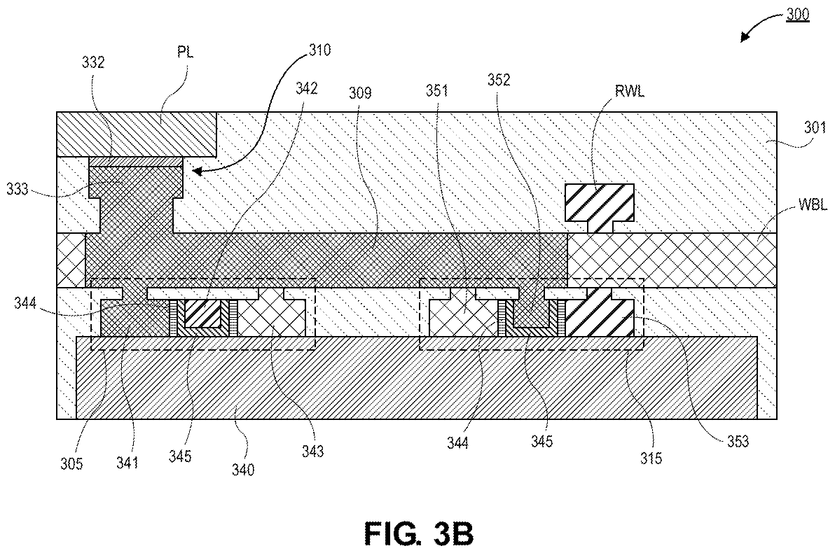

Referring now to FIG. 3A, a cross-sectional illustration of a eDRAM bit cell 300 is shown, in accordance with an embodiment. In an embodiment, the bit cell 300 may comprise a semiconductor fin 340 or other semiconductor body. For example, the semiconductor fin 340 may comprise silicon, germanium, silicon germanium, or any other semiconductor material. In an embodiment, a first transistor 305 and a second transistor 315 are provided on the fin 340 adjacent to each other. That is, both transistors 305 and 315 may be formed on the same fin 340. In other embodiments, the transistors 305 and 315 may be formed on different fins 340.

In an embodiment, each transistor 305 and 315 comprises a source, a gate, and a drain. For the first transistor 305, the source 343 is to the right of the gate 342, and the drain 341 is to the left of the gate 342. A spacer 344 and gate dielectric material 345 may separate the source 343 and the drain 341 from the gate 342. As shown, the drain 341 of the first transistor 305 is electrically coupled to a node 309 that is provided above the transistors 305 and 315. The source 343 may be coupled to the WBL. While portions of the WBL are shown in FIG. 3A, it is to be appreciated that the WBL is behind (or in front of) the node 309. That is, the WBL may run substantially parallel to the node 309 and be in a different plane. The WBL is shown in FIG. 3A in order to show the connection to the source 343 of the first transistor 305. In an embodiment, the gate 342 is electrically coupled to the WWL (not shown in FIG. 3A). The WWL may be out of the plane shown in FIG. 3A. In some embodiments, the WWL may run substantially perpendicular to the node 309 in a layer above the node 309.

In an embodiment, the second transistor 315 may also comprise a source 353, a gate 352, and a drain 351. The source 353 may be electrically coupled to a RWL. The connection to the RWL may be out of the plane of FIG. 3A. The drain 351 may be electrically coupled to a RBL (not shown in FIG. 3A). The RBL may run substantially parallel to the node 309 and the WBL in a different plane. In an embodiment, the gate 352 may be electrically coupled to the node 309.

In an embodiment, the bit cell 300 may further comprise a capacitor 310. In an embodiment, the capacitor 310 is a ferroelectric capacitor. That is, the interface layer 332 between a first terminal 331 and a second terminal 333 may be a ferroelectric material. In an embodiment, the ferroelectric material may comprise doped hafnium oxide such HfₓZr₍₁₋ₓ₎O₂, HfSiO, HfAlO, perovskite materials such as BaTiO₃, or a nitride material such as AlScN. In the particular embodiment shown in FIG. 3A, the capacitor 310 is a trench capacitor. That is, the capacitor 310 includes a terminal 333 that includes a trench. The interface layer 332 lines the trench and the other terminal 331 fills the remainder of the trench. As such, the interface layer 332 may have a U-shaped cross-section. This provides increased capacitance within a relatively small footprint.

The ferroelectric capacitor 310 may be provided in one or more layers above the first transistor 305 and the second transistor 315. Providing a vertically stacked arrangement reduces the surface area of the bit cell 300 and allows for improved memory density. In an embodiment, the ferroelectric capacitor 310 may be provided directly above the first transistor 305. In other embodiments, the ferroelectric capacitor 310 may be provided directly above the second transistor 315. The ferroelectric capacitor 310 may also be provided over both the first transistor 305 and the second transistor 315.

In an embodiment, an interlayer dielectric (ILD) 301 may surround the interconnects over the transistors 305 and 315. The ILD 301 may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD 301 may include pores or air gaps to further reduce their dielectric constant.

Referring now to FIG. 3B, a cross-sectional illustration of an eDRAM bit cell 300 is shown, in accordance with an additional embodiment. In an embodiment, the bit cell 300 in FIG. 3B may be substantially similar to the bit cell 300 in FIG. 3A, with the exception of the ferroelectric capacitor 310. Instead of having a trench configuration, the ferroelectric capacitor 310 may have a planar architecture. In such an embodiment, the top terminal may be omitted, and the PL may directly contact the interface layer 332. The interface layer 332 may have a rectangular cross-section, and the terminal 333 may have a flat top surface instead of a trench. Like the embodiment described above, the terminal 333 may be electrically coupled to the first transistor 305 and the second transistor 315 through the node 309.

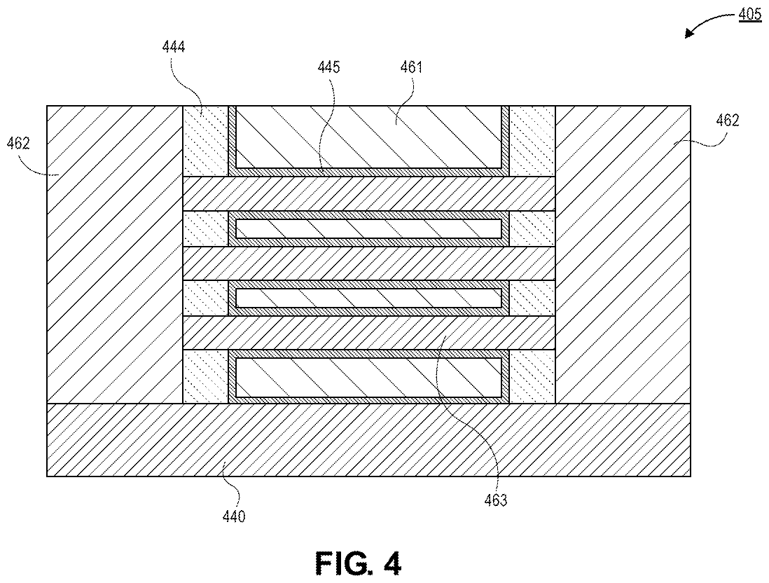

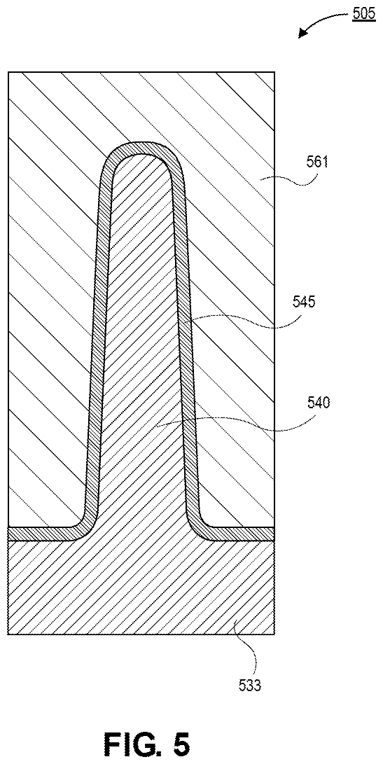

In the embodiments described above, the transistor structure is generically defined. Particularly, it is to be appreciated that any transistor architecture may be used in order to form the bit cells 300. In FIG. 4 and FIG. 5, more detailed illustrations of exemplary transistor structures are shown.

Referring now to FIG. 4, a cross-sectional illustration of a nanowire-based transistor 405 is shown, in accordance with an embodiment. In an embodiment, the transistor 405 may comprise a semiconductor substrate 440. The semiconductor substrate 440 may be a silicon substrate or any other suitable single crystal or thin film semiconductor material. The substrate 440 may be part of a fin in some embodiments. In an embodiment, the transistor 405 comprise a channel region that is surrounded by a gate metal 461. The channel region may include a plurality of nanowires 463. While nanowires 463 are shown, it is to be appreciated that nanoribbon channels or nanosheet channels may also be used in some embodiments. In an embodiment. The nanowires 463 may extend through spacers 444 in order to contact source/drain regions 462. The source/drain regions 462 may be epitaxially grown semiconductor material.

In an embodiment, the nanowires 463 may be lined with a gate dielectric 445. The gate dielectric 445 may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

In an embodiment, the gate metal 461 may comprise one or more conductive layers. The gate metal 461 is formed on the gate dielectric layer 445 and may consist of at least one P-type workfunction metal or N-type workfunction metal, depending on whether the transistor is to be a PMOS or an NMOS transistor. In some implementations, the gate metal 461 may consist of a stack of two or more metal layers, where one or more metal layers are workfunction metal layers and at least one metal layer is a fill metal layer.

Referring now to FIG. 5, a cross-sectional illustration of a fin-based transistor 505 is shown, in accordance with an additional embodiment. As shown, a fin 540 may extend up from a substrate 533, such as a silicon substrate. In an embodiment, the fin 540 may comprise sidewalls that extend up in the vertical direction and a top surface that couples the sidewalls together. The sidewalls may be substantially vertical, or they may be sloped. The top surface may be flat or rounded. In an embodiment, a gate dielectric 545 may line the fin 540. The gate dielectric 545 may be a material similar to any of the gate dielectric materials described in greater detail above. A gate metal 561 may be provided over the gate dielectric 545. The gate metal may be similar to any of the gate metal materials described in greater detail above. The cross-sectional illustration shown in FIG. 5 is a gate-cut, and the source and drain regions are out of the plane of the illustration shown in FIG. 5.

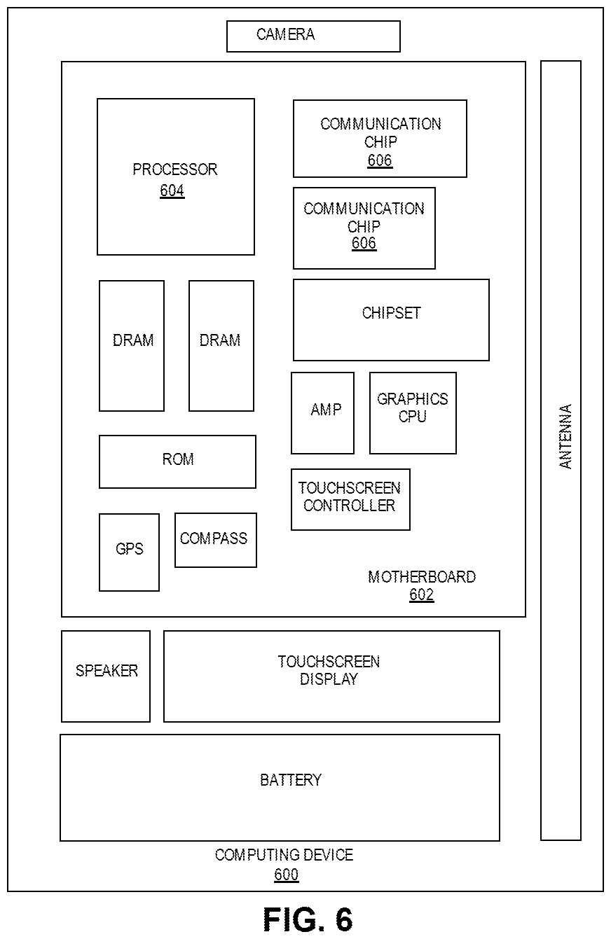

FIG. 6 illustrates a computing device 600 in accordance with one implementation of an embodiment of the present disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. The integrated circuit die of the processor 604 may include one or more structures, such as a memory structure that includes an access transistor, a sense transistor, and a ferroelectric capacitor, built in accordance with implementations of embodiments of the present disclosure. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. The integrated circuit die of the communication chip 606 may include one or more structures, such as a memory structure that includes an access transistor, a sense transistor, and a ferroelectric capacitor, built in accordance with implementations of embodiments of the present disclosure.

In further implementations, another component housed within the computing device 600 may contain an integrated circuit die that includes one or structures, such as a memory structure that includes an access transistor, a sense transistor, and a ferroelectric capacitor, built in accordance with implementations of embodiments of the present disclosure.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

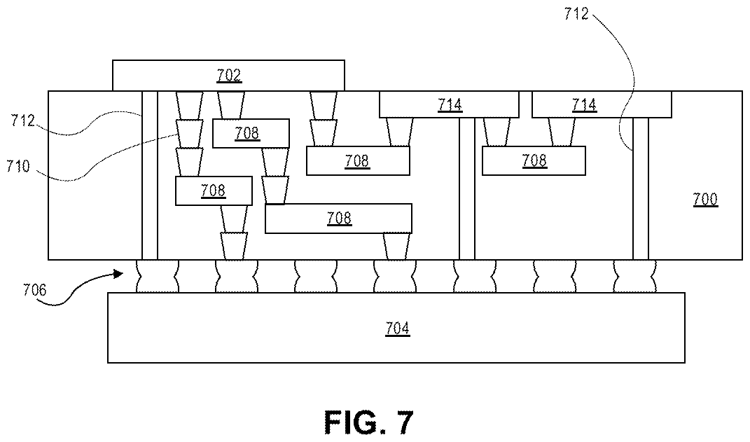

FIG. 7 illustrates an interposer 700 that includes one or more embodiments of the present disclosure. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer 700 may be formed of alternate rigid or flexible materials that may include the same materials described above for use in a semiconductor substrate, such as silicon, germanium, and other group III-V and group IV materials.

The interposer 700 may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrodynamic discharge (ESD) devices. More complex devices such as radio-frequency (RF) devices, power amplifiers, power management devices, antennas, arrays, sensors, and MEMS devices may also be formed on the interposer 700. In accordance with embodiments of the disclosure, apparatuses or processes disclosed herein may be used in the fabrication of interposer 700 or in the fabrication of components included in the interposer 700.

Thus, embodiments of the present disclosure include integrated circuit structures having a memory structure that includes an access transistor, a sense transistor, and a ferroelectric capacitor.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a memory device, comprising: a first transistor, wherein the first transistor is an access transistor to write data; a ferroelectric capacitor for storing data; and a second transistor, wherein the second transistor is a sense transistor to read the data stored on the ferroelectric capacitor.

Example 2: the memory device of Example 1, wherein the first transistor, the second transistor, and the ferroelectric capacitor are coupled together by a node.

Example 3: the memory device of Example 2, wherein the node is coupled to a terminal of the ferroelectric capacitor, a drain of the first transistor and a gate of the second transistor.

Example 4: the memory device of Examples 1-3, wherein the ferroelectric capacitor comprises hafnium, zirconium, and oxygen, or perovskite materials, or aluminum, scandium, and nitrogen.

Example 5: the memory device of Examples 1-4, wherein the ferroelectric capacitor is a planar capacitor.

Example 6: the memory device of Examples 1-4, wherein the ferroelectric capacitor is a trench capacitor.

Example 7: the memory device of Examples 1-6, wherein the ferroelectric capacitor is coupled to a plate line.

Example 8: the memory device of Examples 1-7, wherein a gate of the first transistor is coupled to a write word line, and wherein a drain of the first transistor is coupled to a write bit line.

Example 9: the memory device of Examples 1-8, wherein a source of the second transistor is coupled to a read word line, and wherein a drain of the second transistor is coupled to a read bit line.

Example 10: the memory device of Examples 1-9, wherein the ferroelectric capacitor is stacked above the first transistor and the second transistor.

Example 11: the memory device of Example 10, wherein the ferroelectric capacitor is directly over the first transistor.

Example 12: the memory device of Examples 1-11, wherein the first transistor is laterally adjacent to the second transistor.

Example 13: the memory device of Examples 1-12, wherein the first transistor and the second transistor are planar, fin-based transistors, nanowire-based transistors, nanoribbon-based transistors, or nanosheet-based transistors.

Example 14: a memory device comprising: a semiconductor fin; a first transistor formed on the semiconductor fin; a second transistor formed on the semiconductor fin adjacent to the first transistor; a ferroelectric capacitor over the first transistor; and a node to electrically couple the first transistor, the second transistor, and the ferroelectric capacitor together.

Example 15: the memory device of Example 14, wherein the node is coupled to a terminal of the ferroelectric capacitor, a drain of the first transistor, and a gate of the second transistor.

Example 16: the memory device of Example 14 or Example 15, wherein the first transistor is a write transistor, and wherein the second transistor is a read transistor.

Example 17: the memory device of Examples 14-16, wherein the ferroelectric capacitor comprises hafnium, zirconium, and oxygen, or perovskite materials, or aluminum, scandium, and nitrogen.

Example 18: a computing system, comprising: a board; a device coupled to the board, wherein the device comprises a memory structure, wherein the memory structure, comprises: an access transistor; a sense transistor adjacent to the access transistor; and a ferroelectric capacitor, wherein the ferroelectric capacitor is over the access transistor and the sense transistor.

Example 19: the computing system of Example 18, further comprising: a processor coupled to the board.

Example 20: the computing system of Example 18 or Example 19, further comprising: a communication chip coupled to the board.

What is claimed is:

1. A memory device, comprising:
a first transistor, wherein the first transistor is an access transistor to write data;
a ferroelectric capacitor for storing data; and
a second transistor, wherein the second transistor is a sense transistor to read the data stored on the ferroelectric capacitor.

2. The memory device of claim 1, wherein the first transistor, the second transistor, and the ferroelectric capacitor are coupled together by a node.

3. The memory device of claim 2, wherein the node is coupled to a terminal of the ferroelectric capacitor, a drain of the first transistor and a gate of the second transistor.

4. The memory device of claim 1, wherein the ferroelectric capacitor comprises hafnium, zirconium, and oxygen, or perovskite materials, or aluminum, scandium, and nitrogen.

5. The memory device of claim 1, wherein the ferroelectric capacitor is a planar capacitor.

6. The memory device of claim 1, wherein the ferroelectric capacitor is a trench capacitor.

7. The memory device of claim 1, wherein the ferroelectric capacitor is coupled to a plate line.

8. The memory device of claim 1, wherein a gate of the first transistor is coupled to a write word line, and wherein a drain of the first transistor is coupled to a write bit line.

9. The memory device of claim 1, wherein a source of the second transistor is coupled to a read word line, and wherein a drain of the second transistor is coupled to a read bit line.

10. The memory device of claim 1, wherein the ferroelectric capacitor is stacked above the first transistor and the second transistor.

11. The memory device of claim 10, wherein the ferroelectric capacitor is directly over the first transistor.

12. The memory device of claim 1, wherein the first transistor is laterally adjacent to the second transistor.

13. The memory device of claim 1, wherein the first transistor and the second transistor are planar, fin-based transistors, nanowire-based transistors, nanoribbon-based transistors, or nanosheet-based transistors.

14. A memory device comprising:
a semiconductor fin;
a first transistor formed on the semiconductor fin;
a second transistor formed on the semiconductor fin adjacent to the first transistor;
a ferroelectric capacitor over the first transistor; and
a node to electrically couple the first transistor, the second transistor, and the ferroelectric capacitor together.

15. The memory device of claim 14, wherein the node is coupled to a terminal of the ferroelectric capacitor, a drain of the first transistor, and a gate of the second transistor.

16. The memory device of claim 14, wherein the first transistor is a write transistor, and wherein the second transistor is a read transistor.

17. The memory device of claim 14, wherein the ferroelectric capacitor comprises hafnium, zirconium, and oxygen, or perovskite materials, or aluminum, scandium, and nitrogen.

18. A computing system, comprising:
a board;
a device coupled to the board, wherein the device comprises a memory structure, wherein the memory structure, comprises:
an access transistor;
a sense transistor adjacent to the access transistor; and
a ferroelectric capacitor, wherein the ferroelectric capacitor is over the access transistor and the sense transistor.

19. The computing system of claim 18, further comprising:
a processor coupled to the board.

20. The computing system of claim 18, further comprising:
a communication chip coupled to the board.
